(19) United States
(12) Patent Application Publication
(10) Pub. No.: US 2026/0023203 A1
(43) Pub. Date: Jan. 22, 2026

(54) DISPLAY DEVICE

(71) Applicant: Samsung Display Co., LTD., Yongin-si (KR)

(72) Inventor: SEONG-SIK PARK, Yongin-si (KR)

(21) Appl. No.: 19/037,451

(22) Filed: Jan. 27, 2025

(30) Foreign Application Priority Data
Jul. 16, 2024 (KR) 10-2024-0093863

(51) Int. Cl. G02B 5/30; H10K 59/50; H10K 59/80

(52) U.S. Cl. CPC G02B 5/3016; H10K 59/50; H10K 59/873

(57) ABSTRACT

A display device includes a substrate, a display layer, a thin-film encapsulation layer, and a polarizing unit. The polarizing unit includes a first optical film disposed on the thin-film encapsulation layer and having a first coefficient of moisture expansion, a second optical film disposed on the first optical film and having a second coefficient of moisture expansion, and a third optical film disposed between the first and second optical films and having a third coefficient of moisture expansion. The first and second coefficient of moisture expansion are substantially the same. The first optical film may include a PVA resin film, the second optical film may include a PVA resin film and iodine, and the third optical film may include a λ/4 phase retardation layer. Light passing through the first optical film may be non-polarized, and light passing through the second optical film may be polarized.

This application claims priority to Korean Patent Application No. 10-2024-0093863, filed on Jul. 16, 2024, and all the benefits accruing therefrom under 35 U.S.C. § 119, the content of which in its entirety is herein incorporated by reference.

### BACKGROUND

### 1. Field

The present disclosure relates to a display device, and more specifically, to a display device including a polarizing unit for improving visibility and having enhanced bending characteristics.

### 2. Description of the Related Art

A display device may include a polarizing unit to prevent the reflection of external light for improved visibility. In some cases, the polarizing unit can be arranged in a multi-layer structure within the display device.

Recently, display devices have been developed to have a thin profile and lightweight structure to improve portability. As display devices become thinner, studies have been underway to prevent bending in the polarizing unit for the purpose of improving the reliability of the display device.

### SUMMARY

The present disclosure aims to provide a display device with improved bending characteristics.

According to one embodiment of the present disclosure, the display device includes a substrate, a display layer, a thin-film encapsulation layer, and a polarizing unit. The polarizing unit includes a first optical film disposed on the thin-film encapsulation layer, a second optical film disposed on the first optical film, and a third optical film disposed between the first and second optical films and being in contact with the first and second optical films.

The first optical film may have a first coefficient of moisture expansion, the second optical film may have a second coefficient of moisture expansion, and the third optical film may have a third coefficient of moisture expansion. The first coefficient of moisture expansion and second coefficient of moisture expansion may be substantially the same, while the third coefficient of moisture expansion may differ from the first coefficient of moisture expansion and the second coefficient of moisture expansion. According to an embodiment, the first coefficient of moisture expansion may be greater than the third coefficient of moisture expansion.

According to an embodiment, the first optical film may include a polyvinyl alcohol resin film, the second optical film may include a polyvinyl alcohol resin film and iodine, and the third optical film may include a λ/4 phase retardation layer. Light passing through the first optical film may be non-polarized, and light passing through the second optical film may be polarized.

According to an embodiment, the first optical film may include a cured liquid crystal, the second optical film may include a liquid crystal cured and arranged in an arrangement direction and a dichroic dye aligned in the arrangement direction of the cured liquid crystal, and the third optical film may include a λ/4 phase retardation layer. Light passing through the first optical film may be non-polarized, and light passing through the second optical film may be polarized.

According to an embodiment, the first coefficient of moisture expansion may be smaller than the third coefficient of moisture expansion.

The first and second optical films may each include a λ/4 phase retardation layer, and light passing through the third optical film may be linearly polarized.

According to an embodiment, the third optical film may include a polyvinyl alcohol resin film and iodine.

According to an embodiment, the first optical film may be in direct contact with the thin-film encapsulation layer. According to an embodiment, the display device may further include a touch sensing layer disposed on the thin-film encapsulation layer. The first optical film may be disposed on and in contact with the touch sensing layer. According to an embodiment, the coefficient of thermal expansion of the first and second optical films may be substantially the same.

According to another embodiment of the present disclosure, the display device may include a substrate, a display layer, a thin-film encapsulation layer, and a polarizing unit. The polarizing unit may include an expansion compensation layer disposed on the thin-film encapsulation layer, a phase retardation layer disposed on the expansion compensation layer, and a polarizing layer disposed opposite the expansion compensation layer with the phase retardation layer in between. The coefficient of moisture expansion of the polarizing layer and the coefficient of moisture expansion of the expansion compensation layer may be substantially the same.

According to an embodiment, the expansion compensation layer may include a PVA resin film, and the polarizing layer may include a PVA resin film and iodine. Light passing through the expansion compensation layer may be non-polarized, and light passing through the polarizing layer may be linearly polarized.

According to an embodiment, the phase retardation layer may include a λ/4 phase retardation layer. According to an embodiment, the polarizing unit may be in contact with the thin-film encapsulation layer. According to an embodiment, the display device may further include a touch sensing layer disposed on the thin-film encapsulation layer. The expansion compensation layer may be disposed on and in contact with the touch sensing layer. According to an embodiment, the coefficient of thermal expansion (CTE) of the expansion compensation layer may be substantially the same as the CTE of the polarizing layer.

According to yet another embodiment of the present disclosure, the display device may include a substrate, a display layer, a thin-film encapsulation layer, and a polarizing unit. The polarizing unit may include a first optical film disposed on the thin-film encapsulation layer, a second optical film disposed on the first optical film, and a phase retardation layer disposed between the first and second optical films. The first and second optical films may have substantially the same coefficients of moisture expansion. According to an embodiment, the phase retardation layer may include a λ/4 phase retardation layer, the first optical film may include a PVA resin film, and the second optical film may include a PVA resin film and iodine. Light passing through the first optical film may be non-polarized, and light passing through the second optical film may be polarized. According to an embodiment, the first optical film may be in direct contact with the thin-film encapsulation layer.

According to the embodiments of the present disclosure, the bending of the polarizing unit may be prevented by the first and second optical films included in the display device, thereby providing a display device with improved bending characteristics.

### BRIEF DESCRIPTION OF THE DRAWINGS

These and/or other features will become apparent and more readily appreciated from the following description of the embodiments, taken in conjunction with the accompanying drawings in which:

FIG. 1 is a plan view schematically illustrating a display device according to an embodiment of the present disclosure;

FIG. 2 is a cross-sectional view taken along line A-A′ of FIG. 1;

FIG. 3 is a cross-sectional view schematically illustrating a display device according to an embodiment of the present disclosure;

FIG. 4 is a cross-sectional view schematically illustrating a polarizing unit according to an embodiment of the present disclosure;

FIG. 5 is a cross-sectional view schematically illustrating a polarizing unit according to an embodiment of the present disclosure;

FIG. 6 is a perspective view illustrating a sample of polarizing unit of a comparative example;

FIG. 7 is a perspective view illustrating a sample of polarizing unit according to an embodiment of the present disclosure; and

FIG. 8 is a graph illustrating the change in height of polarizing unit samples according to room-temperature storage time.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are described herein, by referring to the figures, to explain features of the present disclosure.

When an element (or region, layer, portion, or the like) is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. If one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, characteristics, and the like illustrated in the drawings.

Terms such as “first” and “second” may be used in describing various elements, but the elements shall not be restricted to the terms. The terms may be used to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

Moreover, relative terms, such as “below,” “under,” “beneath,” “lower,” “bottom,” “above,” “over,” “upper,” “top,” and the like may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The example term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The example term “below” or “beneath” can therefore encompass an orientation of both above and below.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

In the present specification, if any embodiment can be differently implemented, the specified order of process may be performed differently than the described order. For example, two processes described to be performed sequentially may be performed simultaneously or performed in a reverse order.

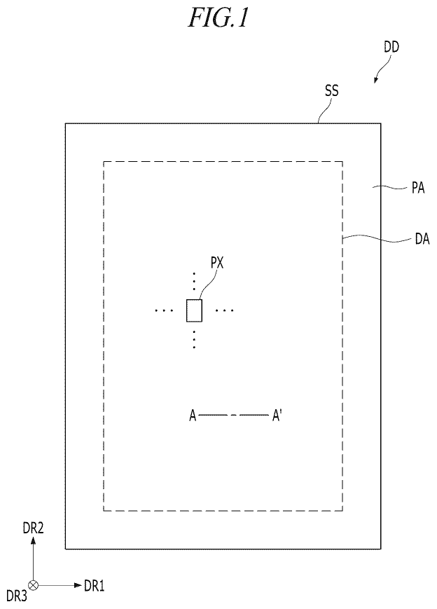

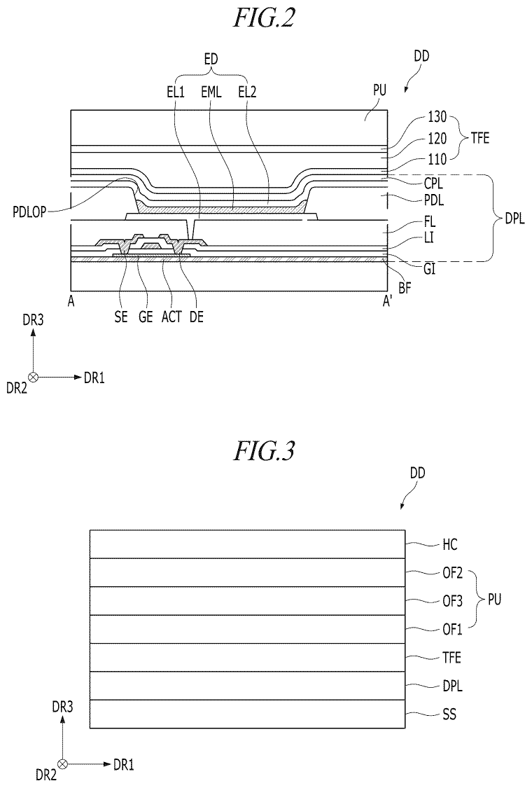

FIG. 1 is a plan view schematically illustrating a display device according to an embodiment of the present disclosure. FIG. 2 is a cross-sectional view taken along line A-A′ of FIG. 1. Referring to FIG. 1, the display device DD may have a display area DA and a peripheral area PA defined therein. In accordance with one or more embodiments of the present disclosure, the display device DD may be implemented in an electronic device (not illustrated). Non-limiting examples of the electronic device include personal computing devices, tablet computers, mobile phones, and the like. Processing circuitry and driving circuitry included in the electronic device may provide voltage and data signals associated with displaying images or video on the display device DD.

The display device DD may include a substrate SS. In this case, the display area DA and the peripheral area PA may be regions defined on the substrate SS. The display area DA of the substrate SS may have a plurality of pixels PX, including light-emitting diodes such as, for example, organic light-emitting diodes, arranged therein. The pixels PX may include thin-film transistors for controlling the light-emitting diodes. Each pixel PX may include at least one thin-film transistor. The peripheral area PA of the substrate SS may have various wirings, for transferring electrical signals applied to the display area DA, arranged therein. The peripheral area PA may have a thin-film transistor disposed therein, and the thin-film transistor may be part of a circuit unit (not illustrated) for controlling electrical signals applied to the display area DA.

Referring to FIG. 2, the display device DD according to an embodiment of the present disclosure may include a substrate SS, a display layer DPL disposed on the substrate and having light-emitting diodes, a thin-film encapsulation layer TFE disposed on the display layer DPL, and a polarizing unit PU disposed on the thin-film encapsulation layer TFE.

The substrate SS may be formed from various materials such as, for example, glass, metal, or plastic. In an embodiment, the substrate SS may be a flexible substrate. For example, the substrate SS may include polymer resins such as, for example, polyethersulfone (PES), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), or cellulose acetate propionate (CAP).

The display layer DPL may be disposed on the substrate SS and include a buffer layer BF, thin-film transistors TR, a gate insulating layer GI, an interlayer insulating layer LI, light-emitting diodes ED electrically connected to the thin-film transistors TR, a pixel defining layer PDL, and a capping layer CPL.

The buffer layer BF may be configured to prevent the diffusion of impurity ions into the substrate SS, block moisture and air infiltration, and planarize the surface. In some embodiments, the buffer layer BF may be formed from inorganic materials such as, for example, silicon oxide, silicon nitride, silicon oxynitride, aluminum oxide, aluminum nitride, titanium oxide, or titanium nitride, or from organic materials such as, for example, polyimide, polyester, or acrylic, or their laminated structures.

The thin-film transistor TR may be configured with an active layer ACT, a gate electrode GE, a source electrode SE, and a drain electrode DE. A gate insulating layer GI may be disposed between the gate electrode GE and the active layer ACT for insulation between the gate electrode GE and the active layer ACT.

The active layer ACT may be disposed on the buffer layer BF. The active layer ACT may be made from inorganic semiconductors such as, for example, amorphous silicon or polycrystalline silicon, or from organic semiconductors. In some embodiments, the active layer ACT may be formed from an oxide semiconductor. For example, the oxide semiconductor may include oxides of materials selected from groups 12, 13, and 14 metal elements such as, for example, zinc (Zn), indium (In), gallium (Ga), tin (Sn), cadmium (Cd), germanium (Ge), or hafnium (Hf), or combinations thereof.

The gate insulating layer GI may be disposed on the buffer layer BF and cover the active layer ACT. The gate electrode GE may be disposed on the gate insulating layer GI.

The interlayer insulating layer LI may be disposed on the gate insulating layer GI and the gate electrode GE and cover the gate electrode GE. Source electrode SE and drain electrode DE may be formed on the interlayer insulating layer LI and may each contact the active layer ACT through a contact hole.

The structure of the thin-film transistor TR is not limited to the examples described herein, and various types of thin-film transistor structures may be applied. For example, although the thin-film transistor TR is formed in a top gate structure, the thin-film transistor TR may be formed in a bottom gate structure in which the gate electrode GE is disposed under the active layer ACT.

In an embodiment, a pixel circuit (not illustrated) including a capacitor may be formed along with the thin-film transistor TR.

A planarization layer FL may be disposed on the source electrode SE, drain electrode DE, and interlayer insulating layer LI, and a light-emitting diode ED may be disposed on the planarization layer FL. The light-emitting diode ED may include a first electrode EL1, a light-emitting layer EML, and a second electrode EL2.

The planarization layer FL may provide a flat upper surface such that the first electrode EL1 can be formed evenly flat. The planarization layer FL may be formed from a single layer or multiple layers of organic or inorganic materials. The planarization layer FL may include common polymer materials such as, for example, benzocyclobutene (BCB), polyimide (PI), hexamethyldisiloxane (HMDSO), polymethylmethacrylate (PMMA), or polystyrene (PS), polymer derivatives with phenolic groups, acrylic polymers, imide polymers, aryl ether polymers, amide polymers, fluorine-based polymers, p-xylylene polymers, vinyl alcohol-based polymers, or blends thereof. In some embodiments, the planarization layer FL may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂). After forming the planarization layer FL, chemical and/or mechanical polishing may be performed in association with providing a flat upper surface.

The planarization layer FL may include an opening that exposes either the source electrode SE or the drain electrode DE of the thin-film transistor TR. The first electrode EL1 may contact the source electrode SE or drain electrode DE through the opening and electrically connect to the thin-film transistor TR.

The light-emitting diode ED is disposed on the planarization layer FL and may include the first electrode EL1, the second electrode EL2 opposite the first electrode EL1, and the light-emitting layer EML disposed between the first electrode EL1 and the second electrode EL2.

The first electrode EL1 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode EL1 may include a reflective layer containing silver (Ag), magnesium (Mg), aluminum (Al), platinum (Pt), palladium (Pd), gold (Au), nickel (Ni), neodymium (Nd), iridium (Ir), chromium (Cr), or compounds thereof. In an embodiment, the first electrode EL1 may further include a layer formed from ITO, IZO, ZnO, or In₂O₃ above or below the reflective layer. For example, the first electrode EL1 may have a multilayer structure of ITO/Ag/ITO.

A pixel defining layer PDL may be disposed on the first electrode EL1 and the planarization layer FL. The pixel defining layer PDL may define the pixels by having openings (PDLOP) corresponding, respectively, to the pixels. The pixel defining layer PDL may also increase the distance between the edges of the first electrode EL1 and the second electrode EL2 to prevent arcing between them. The pixel defining layer PDL may be formed from an organic material such as, for example, polyimide or HMDSO.

A spacer (not illustrated) may be disposed on the pixel defining layer PDL. The spacer may serve to prevent a mask from having a dent during the mask process. The spacer may be formed from an organic material such as, for example, polyimide or HMDSO. The spacer may be formed simultaneously with the pixel defining layer PDL from the same material. In this case, a halftone mask may be used.

The light-emitting layer EML may include an organic material containing fluorescent or phosphorescent substances that emit red, green, blue, or white light. The light-emitting layer EML may be a small molecule or a polymeric organic material, and functional layers such as, for example, a hole transport layer (HTL), a hole injection layer (HIL), an electron transport layer (ETL), and an electron injection layer (EIL) may be selectively disposed above and below the light-emitting layer EML. The light-emitting layer EML may be disposed corresponding to each of the plurality of first electrodes EL1. However, embodiments of the present disclosure are not limited to this configuration, and the light-emitting layer EML may also be integrally formed over the plurality of first electrodes EL1.

The second electrode EL2 may be a transparent or reflective electrode. Alternatively, the second electrode EL2 may be a transparent or translucent electrode and may be formed of a metal thin film including materials such as, for example, ytterbium (Yb), lithium (Li), calcium (Ca), LiF/Ca, LiF/Al, aluminum (Al), silver (Ag), magnesium (Mg), or compounds thereof. In some aspects, a transparent conductive oxide (TCO) layer such as, for example, ITO, IZO, ZnO, or In₂O₃ may be further disposed on the metal thin film. The second electrode EL2 may extend across both the display area DA and the peripheral area PA and may be disposed on the light-emitting layer EML and the pixel defining layer PDL. The second electrode EL2 may be integrally formed with the plurality of light-emitting diodes ED to correspond to the plurality of first electrodes EL1.

Although the light-emitting diode ED is illustrated to include a single light-emitting layer EML in FIG. 2, the embodiment is not limited to this configuration. In an embodiment, the light-emitting diode may include n light-emitting structures (not illustrated) laminated between the first electrode and the second electrode as well as n−1 charge generation layers (not illustrated), where n is a natural number.

Each of the light-emitting structures may include a light-emitting layer EML, a hole functional layer (not illustrated), and an electron functional layer (not illustrated) disposed with the light-emitting layer EML in between. In other words, the light-emitting diode included In an embodiment of the display device may have a tandem structure including a plurality of light-emitting layers. A charge generation layer (not illustrated) may be disposed between adjacent light-emitting structures. The charge generation layer (not illustrated) may include a p-type charge generation layer and/or an n-type charge generation layer.

A capping layer CPL may be disposed on the light-emitting diode ED. Specifically, the capping layer CPL may be disposed on the second electrode EL2. The capping layer CPL may include organic and/or inorganic materials. In the case where the capping layer CPL includes an organic material, the capping layer CPL may include α-NPD, NPB, TPD, m-MTDATA, Alq3, CuPc, TPD15 (N4,N4,N4′,N4′-tetra (biphenyl-4-yl) biphenyl-4,4′-diamine), TCTA (4,4′,4″-Tris (carbazol sol-9-yl) triphenylamine), epoxy resin, or acrylates such as, for example, methacrylate. In the case where the capping layer CPL includes an inorganic material, the capping layer CPL may include alkali metal compounds such as, for example, LiF, alkaline earth metal compounds such as, for example, MgF₂, silicon oxide SiO₂, silicon nitride SiNx, or silicon oxynitride SiON. The capping layer CPL may be a single layer or multiple layers. By providing the capping layer CPL on the light-emitting diode ED, the efficiency of light emitted from the light-emitting diode ED may be improved.

The thin-film encapsulation layer TFE may be disposed on the capping layer CPL. The thin-film encapsulation layer TFE may include at least one inorganic encapsulation layer and at least one organic encapsulation layer. Specifically, the thin-film encapsulation layer TFE may include a first inorganic encapsulation layer 110, an organic encapsulation layer 120, and a second inorganic encapsulation layer 130 that are sequentially stacked thereon.

The first inorganic encapsulation layer 110 may include at least one inorganic material. The first inorganic encapsulation layer 110 may include ceramics, metal oxides, metal nitrides, metal carbides, metal oxynitrides, indium oxide (In₂O₃), tin oxide (SnO₂), indium tin oxide (ITO), silicon oxide, silicon nitride, and/or silicon oxynitride. The first inorganic encapsulation layer 110 may be a single layer or multiple layers.

The organic encapsulation layer 120 may include one or more materials selected from the group consisting of acryl, metacryl, polyester, polyethylene, polypropylene, polyethylene terephthalate (PET), polyethylene naphthalate, polycarbonate, polyimide, polyethylene sulfonate, polyoxymethylene, polyarylate, and hexamethyldisiloxane.

The second inorganic encapsulation layer 130 may cover the organic encapsulation layer 120 and may include ceramics, metal oxides, metal nitrides, metal carbides, metal oxynitrides, indium oxide (In₂O₃), tin oxide (SnO₂), indium tin oxide (ITO), silicon oxide, silicon nitride, and/or silicon oxynitride. The second inorganic encapsulation layer 130 may be a single layer or multiple layers. The second inorganic encapsulation layer 130 may contact the first inorganic encapsulation layer 110 at the edge located outside the display area DA to prevent the organic encapsulation layer 120 from being exposed to the outside.

As the thin-film encapsulation layer TFE includes the first inorganic encapsulation layer 110, the organic encapsulation layer 120, and the second inorganic encapsulation layer 130, even if cracks occur in the thin-film encapsulation layer TFE due to this multilayer structure, the cracks may not propagate between the first inorganic encapsulation layer 110 and the organic encapsulation layer 120 or between the organic encapsulation layer 120 and the second inorganic encapsulation layer 130. This can prevent or minimize the formation of paths for moisture or oxygen to infiltrate the display layer.

The polarizing unit PU may be disposed on the thin-film encapsulation layer TFE. The polarizing unit PU may have a multilayer structure and may improve visibility by preventing the reflection of external light. The polarizing unit PU will be described later in greater detail.

In an embodiment, the display device DD may further include a touch sensing layer TSL disposed on the thin-film encapsulation layer TFE, in which case the polarizing unit PU may be disposed on the touch sensing layer TSL.

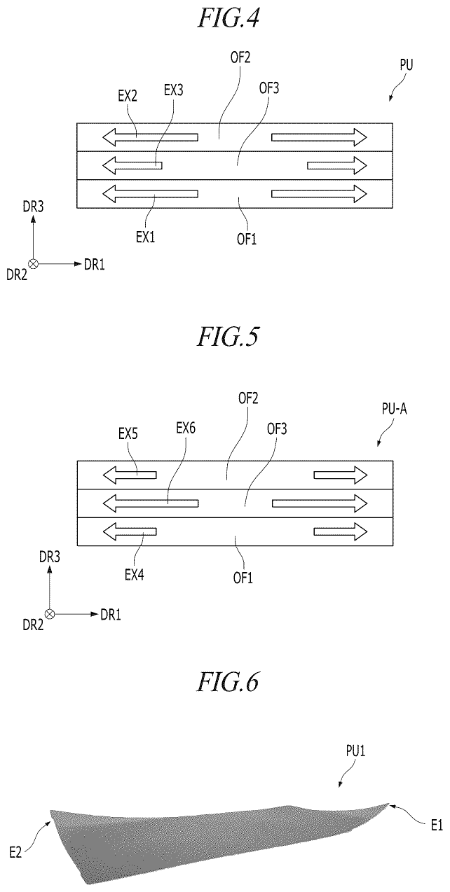

FIG. 3 is a cross-sectional view schematically illustrating a display device according to an embodiment of the present disclosure. FIG. 4 is a cross-sectional view schematically illustrating a polarizing unit according to an embodiment of the present disclosure. FIG. 5 is a cross-sectional view schematically illustrating a polarizing unit according to an embodiment of the present disclosure. Hereinafter, the polarizing unit PU will be mostly described with reference to FIGS. 3 to 5, and any redundant descriptions will be omitted.

Referring to FIG. 3, the polarizing unit PU included in the display device DD according to an embodiment of the present disclosure may be disposed on the thin-film encapsulation layer TFE and may include a first optical film OF1, a second optical film OF2, and a third optical film OF3. The first optical film OF1 may be disposed on the thin-film encapsulation layer TFE, the second optical film OF2 may be disposed on the first optical film OF1, and the third optical film OF3 may be disposed between the first optical film OF1 and the second optical film OF2.

In an embodiment, an adhesive layer (not illustrated) may be included between the thin-film encapsulation layer TFE and the first optical film OF1. The adhesive layer (not illustrated) may include a pressure-sensitive adhesive (PSA).

In an embodiment, the first optical film OF1, the second optical film OF2, and the third optical film OF3 may each include an adhesive layer (not illustrated) and/or an isotropic film. The adhesive layer (not illustrated) may include a pressure-sensitive adhesive (PSA), and the isotropic film may include triacetylcellulose (TAC).

In an embodiment of the disclosure, the first optical film OF1 may have a first coefficient of moisture expansion (CME), the second optical film OF2 may have a second coefficient of moisture expansion, and the third optical film OF3 may have a third coefficient of moisture expansion. The first coefficient of moisture expansion and the second coefficient of moisture expansion may be substantially the same, and the first coefficient of moisture expansion and the second coefficient of moisture expansion may be different from the third coefficient of moisture expansion.

The coefficient of moisture expansion can be defined as the deformation change per unit mass change caused by moisture absorption or desorption. The coefficient of moisture expansion can be calculated by measuring the change in moisture content and the change in deformation between two moisture equilibrium states.

The coefficient of moisture expansion (CME) may be calculated by the following mathematical formula 1:

$$CME = \frac{Δ L}{{L}_{0}} / ( \frac{Δ M}{{M}_{0}} ) \qquad [ Mathematical Formula 1 ]$$

Where, ΔL represents the change in length, Lₒ represents the initial length, ΔM represents the change in mass, and Mₒ represents the initial mass.

In a comparative example, a polarizing unit with two layers having different coefficients of moisture expansion adhered to each other may exhibit different degrees of contraction or expansion in response to changes in humidity. For example, one layer with a relatively larger coefficient of moisture expansion may have a greater degree of deformation than the other layer with a relatively smaller coefficient of moisture expansion. If the deformation due to humidity change is expansion, the degree of expansion of the one layer may be greater than the degree of expansion of the other layer. In this case, the one layer, which expands more than the other layer, may experience tensile force, while the other layer may experience compressive force. As a result, the polarizing unit may bend due to the difference in deformation between the two layers.

In an embodiment of the disclosure, the first optical film OF1, which has a first coefficient of moisture expansion, and the second optical film OF2, which has a second coefficient of moisture expansion substantially the same as the first coefficient, are symmetrically arranged with the third optical film OF3, which has a different coefficient of moisture expansion, in between. This prevents the polarizing unit PU from bending, thereby mitigating deformation in the display device DD.

Referring to FIG. 4, In an embodiment, the first coefficient of moisture expansion may be greater than the third coefficient of moisture expansion. The polarizing unit PU may be symmetrically arranged such that the first optical film OF1, which has a relatively large first coefficient of moisture expansion, and the second optical film OF2, which has a second coefficient of moisture expansion substantially the same as the first coefficient of moisture expansion, are disposed with the third optical film OF3, which has a relatively small third coefficient of moisture expansion, in between.

When moisture absorption occurs in the display device DD due to moisture in the atmosphere, the first optical film OF1 may expand and have a first tensile force EX1 in the first direction DR1, the second optical film OF2 may expand and have a second tensile force EX2 in the first direction DR1, and the third optical film OF3, which is adhered to both the first optical film OF1 and the second optical film OF2, may expand and have a third tensile force EX3 in the first direction DR1. The first optical film OF1 and the second optical film OF2 may expand to substantially the same degree, and the magnitudes of the first tensile force EX1 and the second tensile force EX2 may be substantially the same. Although the magnitudes of the first tensile force EX1 and the second tensile force EX2 are larger than the magnitude of the third tensile force EX3, the symmetrical action of the forces on the upper and lower surfaces of the third optical film OF3 will prevent bending of the polarizing unit PU.

In an embodiment, the first optical film OF1, which has the first coefficient of moisture expansion, may include a polyvinyl alcohol (PVA) resin film, and the second optical film OF2, which has the second coefficient of moisture expansion, may include a PVA resin film and iodine. Iodine, as a dichroic dye, may be adsorbed and oriented within the PVA resin film, absorbing light polarized parallel to the direction of orientation. As a result, light passing through the second optical film OF2 may become linearly polarized. Unlike the second optical film OF2, the first optical film OF1, which does not contain iodine, may allow non-polarized light to pass through. Expressed another way, the first optical film OF1 may pass or transmit light incident the first optical film OF1, without polarizing the light. The second optical film OF2 may linearly polarize light incident the second optical film OF2. Since iodine does not significantly affect, or negligibly affects, the coefficient of moisture expansion of the second optical film OF2, the first coefficient of moisture expansion and the second coefficient of moisture expansion may be substantially the same. In an embodiment, the iodine may be trivalent iodine (I³⁻) ions or pentavalent iodine (I⁵⁻) ions.

The third optical film OF3, which has the third coefficient of moisture expansion, may include a λ/4 phase retardation layer. Light passing through the third optical film OF3 may become circularly polarized. Expressed another way, the third optical film OF3 may circularly polarize light incident the third optical film OF3. In an embodiment, the third optical film OF3 may further include a λ/2 phase retardation layer disposed on the λ/4 phase retardation layer.

The polarizing unit PU according to an embodiment may prevent the reflection of external light as follows. External light may enter the upper side of the polarizing unit PU and pass through the second optical film OF2. The light passing through the second optical film OF2 may become linearly polarized, with only the component perpendicular to the polarization axis of the second optical film OF2 remaining. That is, for example, the second optical film OF2 may linearly polarize light incident the second optical film OF2, in which the second optical film OF2 passes or transmits the component perpendicular to the polarization axis of the second optical film OF2.

The light having passed through the second optical film OF2 may then pass through the third optical film OF3. The light passing through the third optical film OF3 may become circularly polarized with phase shift of λ/4 by the third optical film OF3 including the λ/4 phase retardation layer. The light having passed through the third optical film OF3 may also pass through the first optical film OF1.

The light having passed through the first optical film OF1 may be reflected by the display layer DPL (see FIG. 3) and/or a layer beneath it. The light reflected by the display layer DPL and/or the layer beneath the display layer DPL (referred to as “reflected light” hereinafter) may maintain its circularly polarized state. The reflected light may pass through the first optical film OF1 again. The reflected light having passed through the first optical film OF1 may also pass through the third optical film OF3.

The reflected light passing through the third optical film OF3 may be phase shifted by λ/4 by the λ/4 phase retardation layer included in the third optical film OF3. The reflected light passing through the third optical film OF3 may become linearly polarized and may be parallel to the polarization axis of the second optical film OF2. Therefore, the reflected light having passed through the third optical film OF3 may not be able to pass through the second optical film OF2 but may be absorbed by the second optical film OF2. Accordingly, it is possible for the polarizing unit PU to prevent external light incident at the display device DD from being reflected.

In an embodiment, the first optical film OF1 may include a cured liquid crystal, the second optical film OF2 may include a cured liquid crystal arranged in an arrangement direction and a dichroic dye aligned with the arrangement direction of the cured liquid crystal, and the third optical film OF3 may include a λ/4 phase retardation layer. In an embodiment, the cured liquid crystal may be a cured liquid crystal polymer.

Light passing through the second optical film OF2 may be linearly polarized, and light passing through the third optical film OF3 may become circularly polarized, and thus the polarizing unit PU of an embodiment can prevent external light from being reflected. Since the dichroic dye included in the second optical film OF2 does not significantly affect, or negligibly affects, the coefficient of moisture expansion of the second optical film, the first coefficient of moisture expansion and the second coefficient of moisture expansion may be substantially the same.

In the embodiment described with reference to FIG. 4, the first optical film may be an expansion compensation layer, the second optical film may be a phase retardation layer, and the third optical film may be a polarizing layer.

Referring to FIG. 5, In an embodiment, the first coefficient of moisture expansion may be smaller than the third coefficient of moisture expansion. The polarizing unit PU-A may be symmetrically arranged such that the first optical film OF1, which has a relatively small first coefficient of moisture expansion, and the second optical film OF2, which has a second coefficient of moisture expansion substantially the same as the first coefficient of moisture expansion, are disposed with the third optical film OF3, which has a relatively large third coefficient of moisture expansion, in between.

When moisture absorption occurs in the display device DD due to moisture in the atmosphere, the first optical film OF1 may expand and have a fourth tensile force EX4 in the first direction DR1, the second optical film OF2 may expand and have a fifth tensile force EX5 in the first direction DR1, and the third optical film OF3 may expand and have a sixth tensile force EX6 in the first direction DR1. The first optical film OF1 and the second optical film OF2 may expand to substantially the same degree, and the magnitudes of the fourth tensile force EX4 and the fifth tensile force EX5 may be substantially the same. Although the magnitudes of the fourth tensile force EX4 and the fifth tensile force EX5 are smaller than the magnitude of the sixth tensile force EX6, the symmetrical action of the forces on the upper and lower surfaces of the third optical film OF3 may prevent or reduce bending of the polarizing unit PU-A.

In an embodiment, the first optical film OF1 and the second optical film OF2 may include a λ/4 phase retardation layer, and light passing through the third optical film OF3 may become linearly polarized.

The polarizing unit PU-A according to an embodiment may prevent the reflection of external light as follows. External light may enter the upper side of the polarizing unit PU-A and pass through the second optical film OF2. The light passing through the second optical film OF2 may become circularly polarized, with the light being phase shifted by λ/4, due to the second optical film OF2.

The light having passed through the second optical film OF2 may then pass through the third optical film OF3. The light passing through the third optical film OF3 may become linearly polarized, with only the component perpendicular to the polarization axis of the third optical film OF3 remaining. That is, for example, the third optical film OF3 may linearly polarize light incident the third optical film OF3, in which the third optical film OF3 passes or transmits the component perpendicular to the polarization axis of the third optical film OF3.

The light having passed through the third optical film OF3 may then pass through the first optical film OF1. The light passing through the first optical film OF1 may become circularly polarized, with the light being phase shifted by λ/4, due to the λ/4 phase retardation layer included in the first optical film OF1.

The light having passed through the first optical film OF1 may be reflected by the display layer DPL (see FIG. 3) and/or a layer beneath it. The light reflected by the display layer DPL and/or the layer beneath the display layer DPL (referred to as “reflected light” hereinafter) may maintain its circularly polarized state.

The reflected light may pass through the first optical film OF1 again. The reflected light passing through the first optical film OF1 may become linearly polarized and may be parallel to the polarization axis of the third optical film OF3. Therefore, the reflected light having passed through the first optical film OF1 may not pass through the third optical film OF3 but may be absorbed by the third optical film OF3. Accordingly, it is possible for the polarizing unit PU-A to prevent external light incident at the display device DD from being reflected.

In an embodiment, the first optical film OF1 and the second optical film OF2 may further include λ/2 phase retardation layer disposed on the λ/4 phase retardation layer. In an embodiment, the third optical film OF3 may include a PVA resin film and iodine, and the light passing through the third optical film OF3 may become linearly polarized.

Referring to FIG. 3, In an embodiment, the first optical film OF1 may be disposed on and in direct contact with the thin-film encapsulation layer TFE. In an embodiment of the disclosure, by arranging the polarizing unit PU, which includes the first optical film OF1, directly on the thin-film encapsulation layer TFE, the thickness of the display device DD can be reduced.

In an embodiment, the display device DD may further include a touch sensing layer (not illustrated) disposed on the thin-film encapsulation layer TFE. The first optical film OF1 may be disposed on and in contact with the touch sensing layer (not illustrated). By arranging the polarizing unit PU, which includes the first optical film OF1, directly on the touch sensing layer (not illustrated), the thickness of the display device DD can be reduced.

In an embodiment, the display device DD may further include a touch sensing layer TSL disposed on the thin-film encapsulation layer TFE. The touch sensing layer TSL may obtain coordinate information in response to external inputs, such as, for example, touch. The touch sensing layer TSL may include sensing electrodes (also referred to as touch electrodes) and trace lines (also referred to as signal lines) connected to the sensing electrodes. In an embodiment, the touch sensing layer TSL may be disposed directly on the thin-film encapsulation layer TFE.

In an embodiment, the display device DD may further include a finishing layer (not illustrated) disposed on the thin-film encapsulation layer TFE. The finishing layer (not illustrated) may be directly disposed directly below or above the polarizing unit PU. The finishing layer (not illustrated) may be transparent glass, resin, or film. However, the display device DD according to an embodiment may also be implemented without including a finishing layer (not illustrated).

In an embodiment, the coefficient of thermal expansion (CTE) values of the first optical film OF1 and the second optical film OF2 may be substantially the same. As a result, the first optical film OF1 and the second optical film OF2 are subject to substantially the same contraction and expansion due to changes in temperature, and the polarizing unit PU is prevented from bending as a result of these changes, in addition to the changes in humidity.

Referring to FIG. 3, the display device DD according to an embodiment may further include a hard coating layer HC disposed on the polarizing unit PU. The display device DD may not include a finishing layer (not illustrated) disposed on the polarizing unit PU, and the hard coating layer HC may be directly exposed to the external environment to protect the display device DD. However, the embodiment is not limited to this configuration, and the display device DD may further include both the hard coating layer HC and a finishing layer (not illustrated), and the finishing layer (not illustrated) may be disposed on the hard coating layer HC.

In an embodiment, the display device DD may further include a protective layer (not illustrated) disposed on the hard coating layer HC. The protective layer (not illustrated) may have anti-reflection or low-reflection properties to reduce interface reflection.

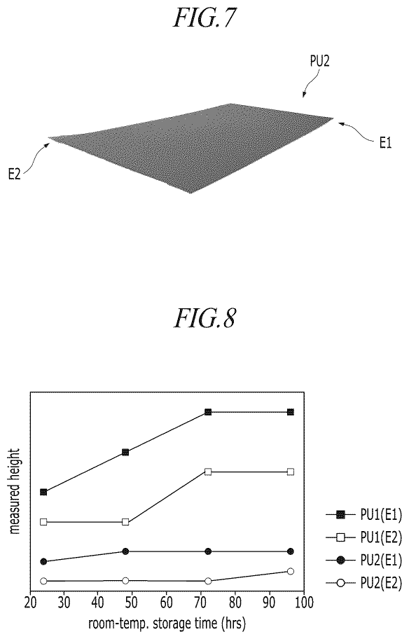

FIG. 6 is a perspective view illustrating a sample of polarizing unit of a comparative example. FIG. 7 is a perspective view illustrating a sample of polarizing unit according to an embodiment of the present disclosure. FIG. 8 is a graph illustrating the change in height of polarizing unit samples according to room-temperature storage time. FIG. 6 illustrates a polarizing unit sample PU1 of the comparative example that has been stored at room temperature for 96 hours. The polarizing unit sample PU1 of the comparative example has a structure in which a polarizing layer, including a PVA resin film, is adhered to a phase retardation layer. Referring to FIG. 6, bending of the polarizing unit sample PU1 is observed, with the sample curling up at a first edge position E1 and a second edge position E2, which is diagonally opposite the first edge position E1.

FIG. 7 is a perspective view illustrating a polarizing unit sample PU2 according to an embodiment of the present disclosure that has been stored at room temperature for 96 hours. Referring to FIG. 7, the bending of the polarizing unit sample PU2 is prevented at a first edge position E1 and a second edge position E2, which is diagonally opposite the first edge position E1. As a result, the polarizing unit sample PU2 has a flatter shape compared to the polarizing unit sample PU1 of the comparative example illustrated in FIG. 6.

FIG. 8 is a graph illustrating the height changes at the first edge position E1 and the second edge position E2 for the polarizing unit sample PU1 of the comparative example and the polarizing unit sample PU2 according to the embodiment of the present disclosure. Referring to FIG. 8, as the room temperature storage time increases, the polarizing unit sample PU1 of the comparative example exhibits bending, resulting in an increase in height at both the first edge position E1 and the second edge position E2. The polarizing unit sample PU2 according to the embodiment of the present disclosure illustrates less height change at the first edge position E1 and the second edge position E2 compared to the polarizing unit sample PU1 of the comparative example, and the bending of the polarizing unit sample PU2 is prevented.

While certain embodiments of the present disclosure have been described herein, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display device, comprising:
a substrate;
a display layer disposed on the substrate and having light-emitting diodes;
a thin-film encapsulation layer disposed on the display layer; and
a polarizing unit disposed on the thin-film encapsulation layer,
wherein:
the polarizing unit comprises:
a first optical film disposed on the thin-film encapsulation layer and having a first coefficient of moisture expansion;
a second optical film disposed on the first optical film and having a second coefficient of moisture expansion; and
a third optical film disposed between the first optical film and the second optical film, being in contact with the first optical film and the second optical film, and having a third coefficient of moisture expansion,
the first coefficient of moisture expansion and the second coefficient of moisture expansion are substantially the same, and
the third coefficient of moisture expansion is different from the first coefficient of moisture expansion and the second coefficient of moisture expansion.

2. The display device of claim 1, wherein the first coefficient of moisture expansion is greater than the third coefficient of moisture expansion.

3. The display device of claim 2, wherein:
the first optical film comprises a polyvinyl alcohol resin film;
the second optical film comprises a polyvinyl alcohol resin film and iodine;
the third optical film comprises a λ/4 phase retardation layer;
light passing through the first optical film is non-polarized; and
light passing through the second optical film is polarized.

4. The display device of claim 1, wherein:
the first optical film comprises a cured liquid crystal;
the second optical film comprises:
a cured liquid crystal arranged in an arrangement direction; and
a dichroic dye aligned with the arrangement direction of the cured liquid crystal of the second optical film;
the third optical film comprises a λ/4 phase retardation layer;
light passing through the first optical film is non-polarized; and
light passing through the second optical film is polarized.

5. The display device of claim 1, wherein the first coefficient of moisture expansion is smaller than the third coefficient of moisture expansion.

6. The display device of claim 1, wherein:
the first optical film and the second optical film each comprise a/4 phase retardation layer; and
light passing through the third optical film is linearly polarized.

7. The display device of claim 6, wherein the third optical film comprises a polyvinyl alcohol resin film and iodine.

8. The display device of claim 1, wherein the first optical film is in direct contact with the thin-film encapsulation layer.

9. The display device of claim 1, further comprising a touch sensing layer disposed on the thin-film encapsulation layer,
wherein the first optical film is disposed on and in contact with the touch sensing layer.

10. The display device of claim 1, wherein a coefficient of thermal expansion of the first optical film and a coefficient of thermal expansion of the second optical film are substantially the same.

11. An electronic device comprising:
a display device, comprising:
a substrate;
a display layer disposed on the substrate and having light-emitting diodes;
a thin-film encapsulation layer disposed on the display layer; and
a polarizing unit disposed on the thin-film encapsulation layer,
wherein:
the polarizing unit comprises:
a first optical film disposed on the thin-film encapsulation layer and having a first coefficient of moisture expansion;
a second optical film disposed on the first optical film and having a second coefficient of moisture expansion; and
a third optical film disposed between the first optical film and the second optical film, being in contact with the first optical film and the second optical film, and having a third coefficient of moisture expansion,
the first coefficient of moisture expansion and the second coefficient of moisture expansion are substantially the same, and
the third coefficient of moisture expansion is different from the first coefficient of moisture expansion and the second coefficient of moisture expansion.

12. The electronic device of claim 11, wherein the first coefficient of moisture expansion is greater than the third coefficient of moisture expansion.

13. The electronic device of claim 12, wherein:
the first optical film comprises a polyvinyl alcohol resin film;
the second optical film comprises a polyvinyl alcohol resin film and iodine;
the third optical film comprises a λ/4 phase retardation layer;
light passing through the first optical film is non-polarized; and
light passing through the second optical film is polarized.

14. The electronic device of claim 11, wherein:
the first optical film comprises a cured liquid crystal;
the second optical film comprises:
a cured liquid crystal arranged in an arrangement direction; and
a dichroic dye aligned with the arrangement direction of the cured liquid crystal of the second optical film;
the third optical film comprises a λ/4 phase retardation layer;
light passing through the first optical film is non-polarized; and
light passing through the second optical film is polarized.

15. The electronic device of claim 11, wherein the first coefficient of moisture expansion is smaller than the third coefficient of moisture expansion.

16. The electronic device of claim 11, wherein:
the first optical film and the second optical film each comprise a λ/4 phase retardation layer; and
light passing through the third optical film is linearly polarized.

17. The electronic device of claim 16, wherein the third optical film comprises a polyvinyl alcohol resin film and iodine.

18. The electronic device of claim 11, wherein the first optical film is in direct contact with the thin-film encapsulation layer.

19. The electronic device of claim 11, further comprising a touch sensing layer disposed on the thin-film encapsulation layer,
wherein the first optical film is disposed on and in contact with the touch sensing layer.

20. The display device of claim 11, wherein a coefficient of thermal expansion of the first optical film and a coefficient of thermal expansion of the second optical film are substantially the same.
